(19) United States
(12) Patent Application Publication
(10) Pub. No.: US 2016/0116542 A1
(43) Pub. Date: Apr. 28, 2016

(54) ESTIMATION DEVICE AND ESTIMATION METHOD

(71) Applicants: KEIO UNIVERSITY, Minato-ku, Tokyo (JP); CALSONIC KANSEI CORPORATION, Saitama-shi, Saitama (JP)

(72) Inventors: Atsushi BABA, Saitama-shi, Saitama (JP); Shuichi ADACHI, Yokohama-shi, Kanagawa (JP)

(73) Assignees: CALSONIC KANSEI CORPORATION, Saitama-shi, Saitama (JP); KEIO UNIVERSITY, Minato-ku, Tokyo (JP)

(21) Appl. No.: 14/895,989

(22) PCT Filed: Jul. 9, 2014
(86) PCT No.: PCT/JP2014/003640

§ 371 Date: Dec. 4, 2015

(30) Foreign Application Priority Data
Sep. 5, 2013 (JP) 2013-184483

(51) Int. Cl. G01R 31/36

(52) U.S. Cl. CPC G01R 31/3651; G01R 31/3606

(57) ABSTRACT

An estimation device and estimation method that can reduce computational load and enhance estimation accuracy in state estimation of an internal state quantity in a nonlinear system are provided. An estimation device (1) estimates an internal state quantity in a nonlinear system using a nonlinear Kalman filter. The nonlinear Kalman filter includes: a prior estimation prediction phase in which a prior state estimate and a prior covariance matrix of a state are calculated based on a state equation relating to the nonlinear system; and a prior estimation update phase in which a prior output estimate, a covariance matrix of an output, and a cross covariance matrix of the state and the output are calculated based on an output equation relating to the nonlinear system. EKF is used in one of the prior estimation prediction phase and the prior estimation update phase, and UKF is used in the other phase.

### CROSS REFERENCE TO RELATED APPLICATION

This application claims priority to Japanese Patent Application No. 2013-184483 filed on Sep. 5, 2013, the entire disclosure of which is incorporated herein by reference.

### TECHNICAL FIELD

The disclosure relates to an estimation device and estimation method for estimating an internal state quantity of a battery or the like.

### BACKGROUND

Kalman filtering has been conventionally used to estimate the state of charge (SOC), parameters, etc. which are each an internal state quantity of a battery installed in an electric vehicle or the like. Since the internal state quantity of the battery is expressed by a nonlinear model, nonlinear Kalman filtering is used to estimate the internal state quantity of the battery. Specific techniques proposed include an estimation technique using the extended Kalman filter (EKF) (for example, Patent Literature (PTL) 1) and an estimation technique using the unscented Kalman filter (UKF) (for example, PTL 2).

### CITATION LIST

### Patent Literatures

PTL 1: JP 2008-519977 A
PTL 2: JP 2009-526220 A

### SUMMARY

### Technical Problem

The estimation technique using the EKF linearly approximates a system at one representative point. In the case where the system to be estimated has simple nonlinearity, that is, the system is weakly nonlinear, high-accuracy estimation is possible with relatively low computational complexity. In the case where the system to be estimated has complex nonlinearity, that is, the system is strongly nonlinear, however, linear approximation at one representative point is insufficient, and estimation accuracy declines.

The estimation technique using the UKF generates a plurality of representative points (sigma points) to perform estimation. Hence, high-accuracy estimation is possible even in the case where the system has complex nonlinearity, that is, the system is strongly nonlinear. With the estimation technique using the UKF, however, calculation is performed for each sigma point, which causes an increase in computational load.

It could be helpful to provide an estimation device and estimation method that can reduce computational load and enhance estimation accuracy in the estimation of an internal state quantity in a nonlinear system such as an internal state quantity of a battery.

### Solution to Problem

An estimation device according to a first aspect is an estimation device for estimating an internal state quantity in a nonlinear system using a nonlinear Kalman filter, wherein the nonlinear Kalman filter includes: a prior estimation prediction phase in which a prior state estimate and a prior covariance matrix of a state are calculated based on a state equation relating to the nonlinear system; and a prior estimation update phase in which a prior output estimate, a covariance matrix of an output, and a cross covariance matrix of the state and the output are calculated based on an output equation relating to the nonlinear system, and an extended Kalman filter (EKF) is used in one of the prior estimation prediction phase and the prior estimation update phase, and an unscented Kalman filter (UKF) is used in the other one of the prior estimation prediction phase and the prior estimation update phase.

An estimation device according to a second aspect is the estimation device according to the first aspect, wherein the EKF is used in a phase corresponding to a weakly nonlinear equation, based on the state equation and the output equation.

An estimation device according to a third aspect is the estimation device according to the first aspect, wherein the UKF is used in a phase corresponding to a strongly nonlinear equation, based on the state equation and the output equation.

An estimation device according to a fourth aspect is the estimation device according to the first aspect, wherein the nonlinear system is a battery, and the internal state quantity includes a state of charge (SOC) of the battery, and the UKF is used in the prior estimation prediction phase, and the EKF is used in the prior estimation update phase.

An estimation method according to a fifth aspect is an estimation method for estimating an internal state quantity in a nonlinear system using a nonlinear Kalman filter, wherein the nonlinear Kalman filter includes: a prior estimation prediction phase in which a prior state estimate and a covariance matrix of a state are calculated based on a state equation relating to the nonlinear system; and a prior estimation update phase in which a prior output estimate, a covariance matrix of an output, and a cross covariance matrix of the state and the output are calculated based on an output equation relating to the nonlinear system, and an extended Kalman filter (EKF) is used in one of the prior estimation prediction phase and the prior estimation update phase, and an unscented Kalman filter (UKF) is used in the other one of the prior estimation prediction phase and the prior estimation update phase.

### Advantageous Effect

The estimation device according to the first aspect uses the EKF in one of the prior estimation prediction phase and the prior estimation update phase, and the UKF in the other phase. In this way, computational load can be reduced in the phase in which calculation is performed with the EKF, and estimation accuracy can be enhanced in the phase in which calculation is performed with the UKF.

The estimation device according to the second aspect uses the EKF in the phase corresponding to the weakly nonlinear equation. The use of the EKF in the phase corresponding to the weakly nonlinear equation can reduce computational load while maintaining a certain level of estimation accuracy.

The estimation device according to the third aspect uses the UKF in the phase corresponding to the strongly nonlinear equation. The use of the UKF in the phase corresponding to the strongly nonlinear equation can efficiently enhance estimation accuracy.

The estimation device according to the fourth aspect uses the UKF in the prior estimation prediction phase and the EKF in the prior estimation update phase, when estimating the internal state quantity of the battery including SOC. The state equation relating to the internal state quantity of the battery is strongly nonlinear, and the output equation relating to the internal state quantity of the battery is weakly nonlinear. The use of the EKF in the prior estimation phase which is weakly nonlinear can reduce computational load while maintaining a certain level of estimation accuracy. The use of the UKF in the prior estimation update phase which is weakly nonlinear can efficiently enhance estimation accuracy.

The estimation method according to the fifth aspect uses the EKF in one of the prior estimation prediction phase and the prior estimation update phase, and the UKF in the other phase. In this way, computational load can be reduced in the phase in which calculation is performed with the EKF, and estimation accuracy can be enhanced in the phase in which calculation is performed with the UKF.

### BRIEF DESCRIPTION OF THE DRAWINGS

In the accompanying drawings:

FIG. 1 is a conceptual diagram illustrating each phase of the Kalman filter;

FIG. 2 is a block diagram of an estimation device according to Example 1;

FIG. 3 is a diagram illustrating an equivalent circuit of a battery;

FIG. 4 is a graph illustrating the SOC-OCV characteristics;

FIG. 5 is a flowchart illustrating the operation of the estimation device according to Example 1;

FIG. 6 is a diagram illustrating measurement data relating to a system to be estimated by the estimation device;

FIG. 7 is a diagram illustrating data of estimation results by the estimation device according to Example 1;

FIG. 8 is a diagram illustrating reference data of estimation results by the EKF; and

FIG. 9 is a diagram illustrating reference data of estimation results by the UKF.

### DETAILED DESCRIPTION

The following describes one of the disclosed embodiments.

### EMBODIMENT

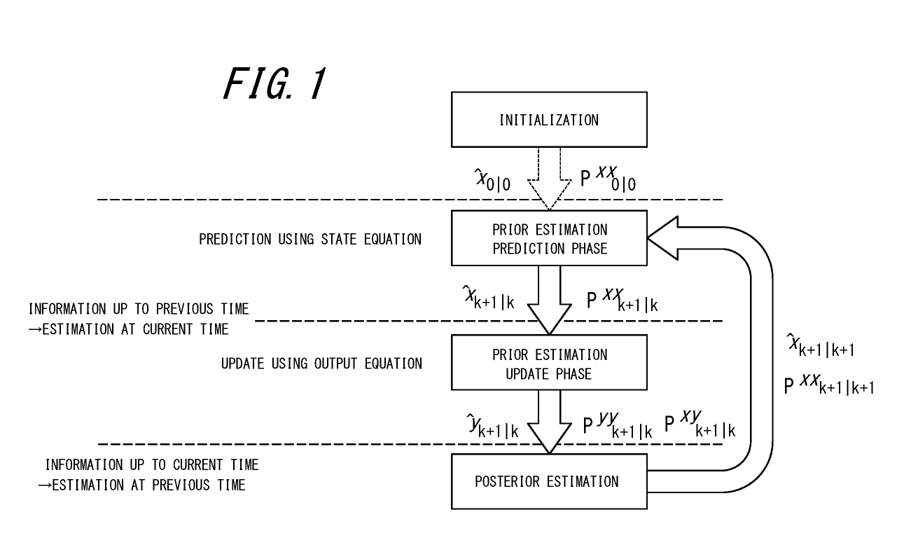

FIG. 1 is a conceptual diagram illustrating each phase of the nonlinear Kalman filter used in an estimation device according to one of the disclosed embodiments. As illustrated in FIG. 1, the nonlinear Kalman filter can be divided into an initialization phase, a prior estimation prediction phase, a prior estimation update phase, and a posterior estimation phase. The disclosure roughly focuses on the fact that the prior estimation prediction phase and the prior estimation update phase in the nonlinear Kalman filter are separate, independent phases, and has a feature that the EKF is used in one of the two phases and the UKF is used in the other phase. Given that the two types of nonlinear Kalman filter, i.e. the EKF and the UKF, are mixed here, the nonlinear Kalman filter according to the disclosure is referred to as the mixed Kalman filter (MKF).

Which of the EKF and the UKF is used in which of the two phases depends on the strength of nonlinearity of each of the state equation corresponding to the prior estimation prediction phase and the output equation corresponding to the prior estimation update phase. The phase corresponding to the strongly nonlinear equation of these equations uses the UKF. The phase corresponding to the weakly nonlinear equation of these equations uses the EKF. For example, in the case where the state equation is strongly nonlinear and the output equation is weakly nonlinear, the prior estimation prediction phase uses the UKF, and the prior estimation update phase uses the EKF. In the case where the output equation is strongly nonlinear and the state equation is weakly nonlinear, the prior estimation prediction phase uses the EKF, and the prior estimation update phase uses the UKF.

Various methods are available in determining the strength of nonlinearity of each of the state equation and the output equation. For example, in the case where an equation (the state equation or the output equation) can be approximated by a predetermined linear equation within a fixed error range, the nonlinearity of the equation is regarded as weak. In the case where the equation cannot be approximated by the predetermined linear equation within the fixed error range, the nonlinearity of the equation is regarded as strong. In the case where the equation is indifferentiable, the nonlinearity of the equation is regarded as strong.

The following describes each phase illustrated in FIG. 1 in detail. Suppose a discrete nonlinear system with noise being taken into account is subjected to estimation. The state equation relating to the nonlinear system is represented by Expression (1), and the output equation relating to the nonlinear system is represented by Expression (2).

[Math. 1]

xₖ₊₁=f_{d}(xₖ,uₖ)+vₖ (1)

yₖ=h_{d}(xₖ,uₖ)+ωₖ (2)

In Expressions (1) and (2), a state variable is xε [symbol] ⁿ, input is uε [symbol] ⁿ, output is yε [symbol] ⁿ, process noise is v˜N(0,Q), sensor noise is ω˜N(0,r), and f_{d} and h_{d} are nonlinear functions.

(1 Initialization Phase)

In the initialization phase, an initial value of the state estimate and an initial value of the covariance matrix of the state (the initial covariance matrix of the state) are given. The initial value of the state is represented by Expression (3), and the initial covariance matrix is represented by Expression (4).

[Math. 2]

\hat{x}_{q0}=E[x₀] (3)

P_{0|0}^{xx}=E└(x₀−\hat{x}₀)(x₀−\hat{x}₀)^{T}┘ (4)

(2 Prior Estimation Prediction Phase)

In the prior estimation prediction phase which follows, the prior state estimate and the prior covariance matrix of the state are calculated (predicted) based on the state equation. The method of calculating the prior estimate and the prior covariance matrix based on the state equation differs between when the EKF is used and when the UKF is used. The following describes each of the case of using the EKF in the phase and the case of using the UKF in the phase.

(2.1 Prior Estimation Prediction Phase Using EKF)

In the case of using the EKF in the prior estimation prediction phase, the prior state estimate and the prior covariance matrix of the state at time k+1 are calculated (predicted) based on the posterior state estimate and the posterior covariance matrix of the state at time k (the respective initial values in the case where k=0), and the state equation. In detail, the prior state estimate \hat{x}_{k-1|k} is calculated according to Expression (5), and the prior covariance matrix P_{k+1|k}^{xx} of the state is calculated according to Expressions (6) and (7).

$$\begin{matrix}[ Math . 3 ] & \\ {\hat{x}}_{k + 1 \vert k} = {f}_{d} ( {\hat{x}}_{k \vert k} {u}_{k} ) & ( 5 ) \\ {P}_{k + 1 \vert k}^{xx} = {A}_{k} {P}_{k \vert k}^{xx} {A}_{k}^{T} + Q & ( 6 ) \\ {A}_{k} ≡ \frac{\partial {f}_{d} ( x , {u}_{k} )}{\partial x} {\vert}_{x = {\hat{x}}_{k \vert k}} & ( 7 )\end{matrix}$$

(2.2 Prior Estimation Prediction Phase Using UKF)

The following describes the case of using the UKF in the prior estimation prediction phase. In the case of using the UKF in the prior estimation prediction phase, first each sigma point (x_{k|k}⁰˜x_{k|k}ⁿ) corresponding to x is generated from the posterior state estimate at time k based on the following Expressions (8) to (10).

[Math. 4]

X_{k|k}⁰=\hat{x}_{k|k} (8)

X_{k|k}ⁱ=\hat{x}_{k|k}+\sqrt{nₓ+κ}L_{k|k}ⁱ i=1 . . . nₓ (9)

X_{k|k}ⁱ⁺ⁿ^{ₓ}==\hat{x}_{k|k}−\sqrt{nₓ+κ}L_{k|k}ⁱ i=1 . . . nₓ (10)

Here, L_{k|k}¹ is the i-th column component of the matrix square root L_{k|k}, and the matrix square root L_{k|k} satisfies L_{k|k}L_{k|k}^{T}=P_{k|k}ⁿ. Meanwhile, κ is a parameter for scaling, and is preferably set so that nₓ+κ=3 in the case where the state variable x has noise that follows a normal distribution.

After generating the sigma points, the estimate is calculated for each sigma point from the following Expression (11) which is based on the state equation.

[Math. 5]

X_{k+1|k}ⁱ=f_{d}(X_{k|k}ⁱ,uₖ) (11)

Next, the prior state estimate is calculated based on the following Expression (12), and the prior covariance matrix of the state is calculated based on the following Expression (13).

$$\begin{matrix}[ Math . 6 ] & \\ {\hat{x}}_{k + 1 \vert k + 1} = {\sum }_{i = 0}^{2 {n}_{x}} {w}_{a}^{i} {k + 1 \vert k}_{i}^{} & ( 12 ) \\ {P}_{k + 1 \vert k}^{xx} = {\sum }_{i = 0}^{2 {n}_{x}} {w}_{a}^{i} ( {k + 1 \vert k}_{i}^{} - {\hat{x}}_{k + 1 \vert k} ) {( {k + 1 \vert k}_{i}^{} - {\hat{x}}_{k + 1 \vert k} )}^{T} + Q & ( 13 )\end{matrix}$$

In Expressions (12) and (13), wₐⁱ is a weight for each sigma point, and is set based on the following Expressions (14) to (16). Meanwhile, κ is a parameter for scaling, and is preferably set so that nₓ+κ=3 in the case where the state variable x has noise that follows a normal distribution, as in the above-mentioned case.

$$\begin{matrix}[ Math . 7 ] & \\ {w}_{a}^{0} = \frac{κ}{{n}_{x} + κ} & ( 14 ) \\ {w}_{a}^{i} = \frac{κ}{2 ( {n}_{x} + κ )} i = 1 … {n}_{x} & ( 15 ) \\ {w}_{a}^{i + {n}_{x}} = \frac{κ}{2 ( {n}_{x} + κ )} i = 1 … {n}_{x} & ( 16 )\end{matrix}$$

(3 Prior Estimation Update Phase)

In the prior estimation prediction phase which follows the prior estimation prediction phase, the prior output estimate, the covariance matrix of the output, and the cross covariance matrix of the state and the output are calculated based on the prior state estimate and the prior covariance matrix of the state calculated in the prior estimation prediction phase and the output equation. The method of calculating these values differs between when the EKF is used and when the UKF is used. The following describes each of the case of using the EKF in the phase and the case of using the UKF in the phase.

(3.1 Prior Estimation Update Phase Using EKF)

In the case of using the EKF in the prior estimation update phase, the output at time k+1 is calculated (updated) based on the prior state estimate and the prior covariance matrix of the state at time k+1, and the output equation. In detail, the prior output estimate ŷ_{k+1|k} is calculated according to Expression (17), the covariance matrix P_{k+1|k}^{yy} of the output is calculated according to Expressions (18) and (20), and the cross covariance matrix P_{k+1|k}^{xy} of the state and the output is calculated according to Expressions (19) and (20).

$$\begin{matrix}[ Math . 8 ] & \\ {\hat{y}}_{k + 1 \vert k} = {h}_{d} ( {\hat{x}}_{k + 1 \vert k} , {u}_{k} ) & ( 17 ) \\ {P}_{k + 1 \vert k}^{yy} = {C}_{k + 1} {P}_{k + 1 \vert k}^{xx} {C}_{k + 1}^{T} + r & ( 18 ) \\ {P}_{k + 1 \vert k}^{xy} = {P}_{k + 1 \vert k}^{xx} {C}_{k + 1}^{T} & ( 19 ) \\ {C}_{k + 1} ≡ \frac{\partial {h}_{d} ( x , {u}_{k} )}{\partial x} {\vert}_{x = {\hat{x}}_{k + 1 \vert k}} & ( 20 )\end{matrix}$$

(3.2 Prior Estimation Update Phase Using UKF)

In the case of using the EKF in the prior estimation update phase, first the sigma point V corresponding to y is generated based on the following Expression (21).

[Math. 9]

y_{k+1|k}ⁱ=h_{d}(X_{k+1|k}ⁱ,uₖ) (21)

Next, the prior output estimate is calculated based on the following Expression (22), and the covariance matrix of the output and the cross covariance matrix of the state and the output are calculated (updated) respectively based on the following Expressions (23) and (24).

$$\begin{matrix}[ Math . 10 ] & \\ {\hat{y}}_{k + 1 \vert k} = {\sum }_{i = 0}^{2 {n}_{x}} {w}_{b}^{i} {k + 1 \vert k}_{i}^{} & ( 22 ) \\ {P}_{k + 1 \vert k}^{yy} = {\sum }_{i = 0}^{2 {n}_{x}} {w}_{b}^{i} ( {k + 1 \vert k}_{i}^{} - {\hat{y}}_{k + 1 \vert k} ) {( {k + 1 \vert k}_{i}^{} - {\hat{y}}_{k + 1 \vert k} )}^{T} + r & ( 23 ) \\ {P}_{k + 1 \vert k}^{xy} = {\sum }_{i = 0}^{2 {n}_{x}} {w}_{b}^{i} ( {k + 1 \vert k}_{i}^{} - {\hat{x}}_{k + 1 \vert k} ) {( {k + 1 \vert k}_{i}^{} - {\hat{y}}_{k + 1 \vert k} )}^{T} & ( 24 )\end{matrix}$$

In Expressions (22) to (24), w_{b}ⁱ is a weight for each sigma point, and is set based on the following Expressions (25) to (26). Meanwhile, κ is a parameter for scaling, and is preferably set so that nₓ+κ=3 in the case where the state variable x has noise that follows a normal distribution, as in the above-mentioned case.

$$\begin{matrix}[ Math . 11 ] & \\ {w}_{b}^{0} = \frac{κ}{{n}_{x} + κ} & ( 25 ) \\ {w}_{b}^{i} = \frac{κ}{2 ( {n}_{x} + κ )} i = 1 … {n}_{x} & ( 26 ) \\ {w}_{b}^{i + {n}_{x}} = \frac{κ}{2 ( {n}_{x} + κ )} i = 1 … {n}_{x} & ( 27 )\end{matrix}$$

(4 Posterior Estimation Phase)

Next, based on the observation value yₖ₊₁ and the prior output estimate ŷ_{k+1|k} at time k+1, the prior state estimate and the prior covariance matrix of the state at time k+1 are corrected according to the following Expressions (28) and (29), thus yielding the posterior state estimate and the posterior covariance matrix of the state. In Expressions (28) and (29), Kₖ₊₁ is the Kalman gain, which is calculated according to Expression (30).

[Math. 12]

\hat{x}_{k+1|k+1}=\hat{x}_{k+1|k}+Kₖ₊₁(yₖ₊₁−ŷ_{k+1|k}) (28)

P_{k+1|k+1}^{xx}=P_{k+1|k}^{xx}+Kₖ₊₁P_{k+1|k}^{yy}Kₖ₊₁^{T} (29)

Kₖ₊₁=P_{k+1|k}^{xy}(P_{k+1|k}^{yy})⁻¹ (30)

The procedure then returns to the prior estimation prediction phase, and repeats the prior estimation prediction phase to the posterior estimation phase using the posterior state estimate and the posterior covariance matrix of the state yielded in the posterior estimation phase.

### Example 1

### Estimation of Internal State Quantity of Battery

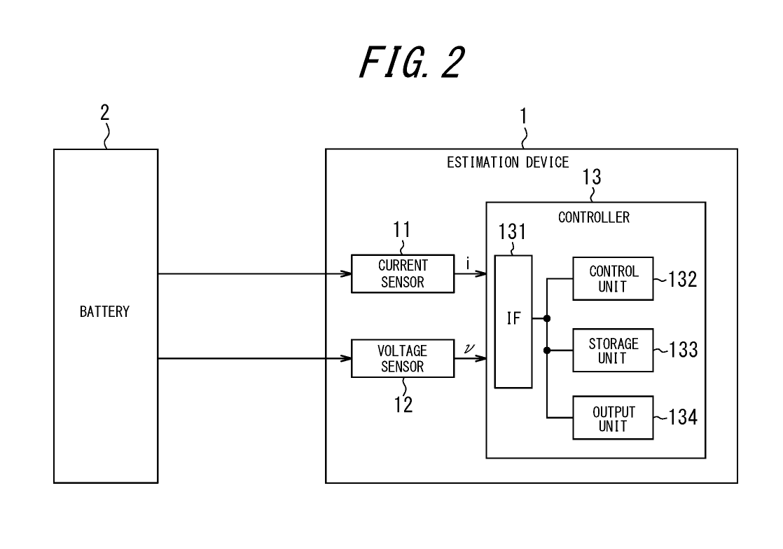

The following describes an estimation device for estimating an internal state quantity of a battery using the above-mentioned MKF algorithm. The internal state quantity of the battery includes the state of charge (SOC) of the battery. An estimation device 1 described here is installed in an electric vehicle as an example. FIG. 2 is a block diagram including the estimation device 1 according to Example 1. The estimation device 1 according to Example 1 is connected to a battery 2, and includes a current sensor 11, a voltage sensor 12, and a controller 13.

The battery 2 is a rechargeable battery. In this example, the battery 2 is a lithium ion battery. The battery 2 in this example is, however, not limited to a lithium ion battery, and may be any of the other types of batteries such as a nickel metal hydride battery.

The current sensor 11 detects the magnitude of discharge current in the case where the battery 2 supplies power to, for example, an electric motor for driving the vehicle. The current sensor 11 also detects the magnitude of charge current in the case where the battery 2 recovers part of braking energy from the electric motor functioning as a power generator during braking or is charged from a ground power source. The current sensor 11 outputs the detected charge and discharge current signal i to the controller 13 as an input signal.

The voltage sensor 12 detects the value of voltage between the terminals of the battery 2. The voltage sensor 12 outputs the detected terminal voltage signal v to the controller 13. The current sensor 11 and the voltage sensor 12 may have any of various structures and forms as appropriate.

The controller 13 is realized by a microcomputer as an example. The controller 13 includes an interface unit 131, a control unit 132, a storage unit 133, and an output unit 134.

The interface unit 131 receives the charge and discharge current signal i output from the current sensor 11 and the terminal voltage signal v output from the voltage sensor 12.

The control unit 132 performs various controls relating to the controller 13. In detail, the control unit 132 estimates the internal state quantity of the battery 2 according to the MKF, based on the charge and discharge current signal i and terminal voltage signal v received by the interface unit 131 and a battery equivalent circuit model for the battery 2. The storage unit 133 stores various programs and the like necessary for the estimation by the controller 13. The output unit 134 outputs estimation results by the control unit 132.

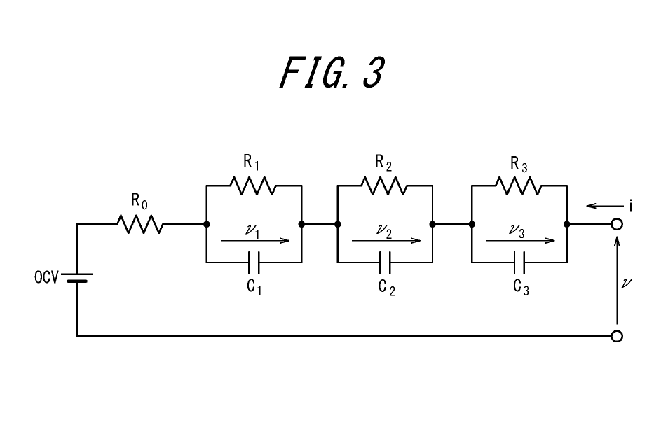

FIG. 3 illustrates the battery equivalent circuit model used in this example. This is the combination of an approximate model of Warburg impedance using the Foster circuit proposed by Kuhn and the like and open circuit voltage (OCV) proposed by Plett and the like.

Here, the state variable x, the input u, and the output y are respectively defined as shown by the following Expressions (31) to (33).

[Math. 13]

x=[z_{soc}v₁v₂V₃] (31)

u=i (32)

y=v (33)

In Expressions (31) to (33), z_{soc} is the state of charge (SOC), v1 to v3 are each the voltage drop in the capacitor corresponding to the subscript, i is the current flowing through the whole circuit, and v is the voltage drop in the whole circuit.

Then, the state space representation of the battery equivalent circuit model in FIG. 3 is indicated by the following Expressions (34) to (38).

$$\begin{matrix}[ Math . 14 ] & \\ \dot{x} ( t ) = {F}_{f} x ( t ) + {G}_{f} u ( t ) & ( 34 ) \\ y ( t ) = {f}_{OCV} ( {z}_{SOC} ) + {H}_{f} x ( t ) + {R}_{0} u ( t ) & ( 35 ) \\ {F}_{f} = diag ( 0 , - \frac{1}{{C}_{1} {R}_{1}} , - \frac{1}{{C}_{2} {R}_{2}} , - \frac{1}{{C}_{3} {R}_{3}} ) & ( 36 ) \\ {G}_{f} = {[ \begin{matrix}\frac{1}{{C}_{0}} & \frac{1}{{C}_{1}} & \frac{1}{{C}_{2}} & \frac{1}{{C}_{3}}\end{matrix} ]}^{T} & ( 37 ) \\ {H}_{f} = [ \begin{matrix}0 & 1 & 1 & 1\end{matrix} ] \\ where & ( 38 ) \\ [ Math . 15 ] & \\ {C}_{n} = \frac{{C}_{d}}{2} n = 1 , 2 , 3 & ( 39 ) \\ {R}_{n} = \frac{8 {R}_{d}}{{( 2 n - 1 )}^{2} {π}^{2}} n = 1 , 2 , 3 & ( 40 )\end{matrix}$$

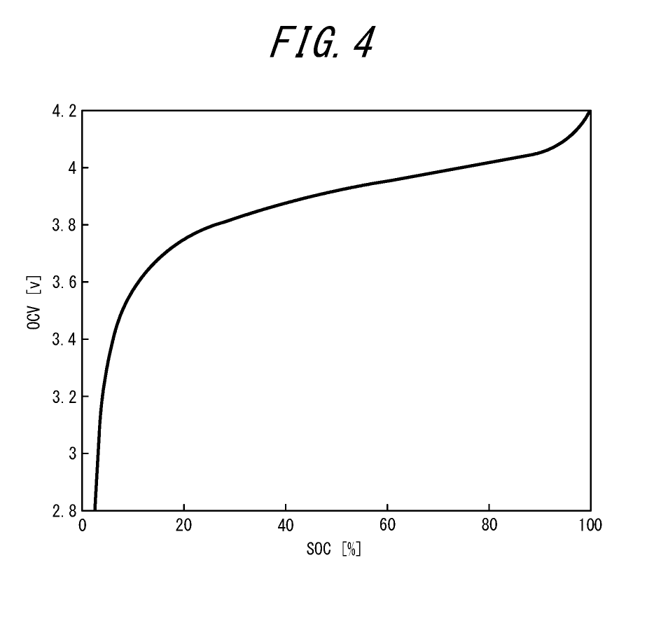

In Expression (35), f_{ocv}(z_{soc}) is a function representing the nonlinear relationship between the SOC and the OCV. FIG. 4 illustrates this SOC-OCV function. The SOC is defined as follows, where C₀ is the full charge capacity of the battery.

$$\dot{z} = \frac{i}{{C}_{0}} \qquad [ Math . 16 ]$$

Moreover, in this example, for high-accuracy estimation of the parameters of the battery 2, too, the natural logarithm is taken for each parameter and added to the state variable x to form a spreading system. The state variable z of the spreading system is defined as follows.

[Math. 17]

z=└z_{soc}v₁v₂v₃α_{R}_{₀}α_{R}_{_{d}}α_{C}_{_{d}}┘ (42)

where

[Math. 18]

α_{R}_{₀}=ln R₀ (43)

α_{R}_{_{d}}=ln R_{d} (44)

α_{C}_{_{d}}=ln C_{d} (45)

Expressions (34) and (35) can then be rewritten respectively as the following state equation (Expression (46)) and output equation (Expression (47)) as the spreading system.

[Math. 19]

\dot{z}(t)=f(z(t),u(t)) (46)

y(t)=h(z(t),u(t)) (47)

where

$$\begin{matrix}[ Math . 20 ] & \\ f ( z ( t ) , u ( t ) ) = [ \begin{matrix}\frac{i}{{C}_{0}} \\ - \frac{{π}^{2} {v}_{1}}{4 exp ( {α}_{{c}_{d}} + {α}_{{R}_{d}} )} + \frac{2 i}{exp ( {α}_{{c}_{d}} )} \\ - \frac{9 {π}^{2} {v}_{2}}{4 exp ( {α}_{{c}_{d}} + {α}_{{R}_{d}} )} + \frac{2 i}{exp ( {α}_{{c}_{d}} )} \\ - \frac{25 {π}^{2} {v}_{3}}{4 exp ( {α}_{{c}_{d}} + {α}_{{R}_{d}} )} + \frac{2 i}{exp ( {α}_{{c}_{d}} )} \\ 0 \\ 0 \\ 0\end{matrix} ] & ( 48 ) \\ h ( z ( t ) , u ( t ) ) = {f}_{OCV} ( {z}_{SOC} ) + {v}_{1} + {v}_{2} + {v}_{3} + exp ( {α}_{{R}_{0}} ) i & ( 49 )\end{matrix}$$

Expressions (48) and (49) are derived from Expressions (34) to (45). The control unit 132 applies the MKF to the spreading system represented by Expressions (46) to (49).

The state equation represented by Expression (46) is strongly nonlinear, and the output equation represented by Expression (47) is weakly nonlinear. Accordingly, in this example, the UKF is used in the prior estimation prediction phase, and the EKF is used in the prior estimation update phase.

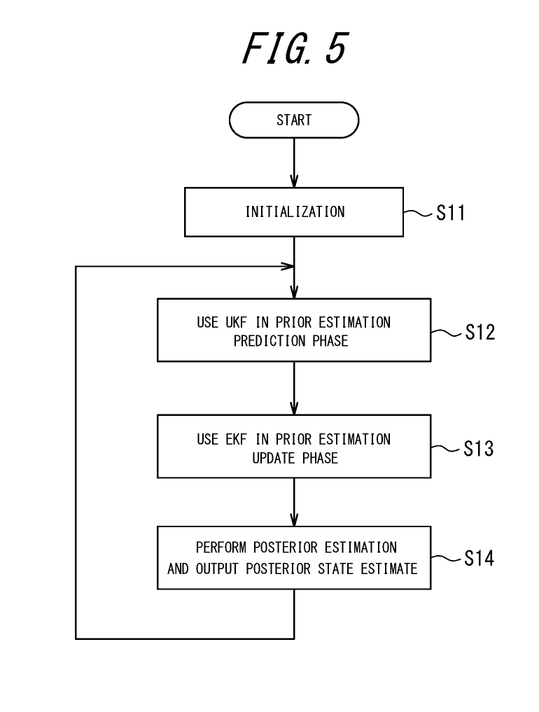

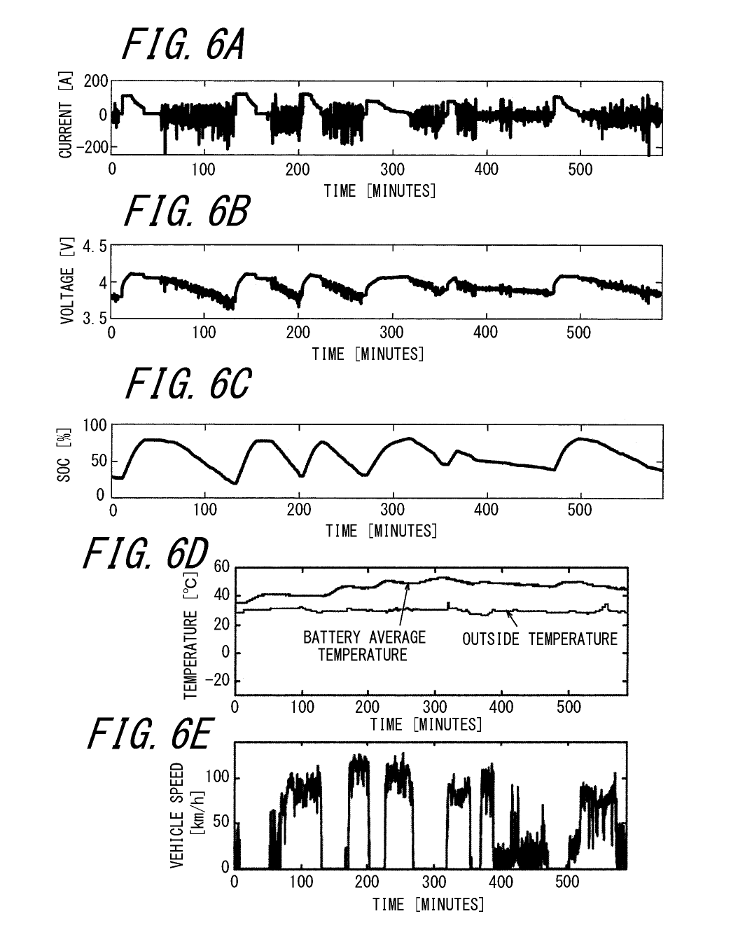

The following describes the simulation operation of the estimation device 1 according to the disclosure, with reference to a flowchart in FIG. 5. As observation values necessary for simulation, measurement data by the current sensor 11 and the voltage sensor 12 when actually driving the electric vehicle from a point A to another point B is used. FIG. 6 illustrates the measurement data. FIGS. 6(a) and (b) respectively illustrate the current between the terminals of the battery 2 and the voltage between the terminals of the battery 2. FIGS. 6(c), (d), and (e) respectively illustrate measurement data of the SOC, temperature, and vehicle speed of the battery 2, for reference. In FIG. 6(a) to (e), the horizontal axis indicates time, with the vehicle starting from the point A at 0-minute time and reaching the point B at about 600-minute time.

Referring back to FIG. 5, the operation of the estimation device 1 is described below. First, the control unit 132 initializes each variable (step S11). In detail, the following actual measurement values are used as the initial values.

[Math. 21]

\ddot{z}_{0|0}=[0.301 0 0 0 −7.18 −7.24 11.3]^{T} (50)

P_{0|0}^{zz}=diag(0.1,10⁴,10⁴,10⁴,10⁻⁸,10⁻⁶,10⁴) (51)

Q=diag(10⁻⁴,10⁻⁵,10⁻⁵,10⁻⁵,10⁻⁶,10⁻⁶,10⁻⁸) (52)

r=0.3 (53)

Next, the control unit 132 uses the UKF in the prior estimation prediction phase (step S12), to calculate (predict) the prior state estimate and the prior covariance matrix of the state. The prior estimation prediction phase is based on the state equation of Expression (46). Here, in order to perform discrete-time numerical simulation, Expression (46) which is a continuous-time state equation is converted into a discrete-time state equation by the Runge-Kutta method. The method of converting the continuous-time state equation into the discrete-time state equation is not limited to the Runge-Kutta method, and may be any discretization method such as the Euler method.

Next, the control unit 132 uses the EKF in the prior estimation update phase (step S13), to calculate the prior output estimate, the covariance matrix of the output, and the cross covariance matrix of the state and the output based on the prior state estimate and the prior covariance matrix of the state calculated in the prior estimation prediction phase and the output equation. The partial differential for f_{ocv}(z_{soc}) in the output equation is calculated by numerical analysis based on the data in FIG. 4. Alternatively, f_{ocv}(z_{soc}) may be subjected to function approximation by the following Expression (54), and the function may be partially differentiated algebraically.

$$\begin{matrix} [ Math . 22 ] & \\ {f}_{OCV} ( {z}_{SOC} ) = {K}_{0} - \frac{{K}_{1}}{{z}_{SOC}} - {K}_{2} {z}_{SOC} + {K}_{3} ln ( {z}_{SOC} ) + {K}_{4} ln ( 1 - {z}_{SOC} ) & ( 54 )\end{matrix}$$

where K₀ to K₄ in Expression (54) are coefficient parameters.

The control unit 132 then corrects the prior state estimate and the prior covariance matrix of the state based on the observation values measured by the current sensor 11 and the voltage sensor 12 and the prior output estimate calculated in the prior estimation update phase, thus yielding the posterior state estimate and the posterior covariance matrix of the state. The output unit 134 outputs the posterior state estimate as the output value (step S14). The operation then returns to step S12, and the processes of steps S12 to S14 are repeated.

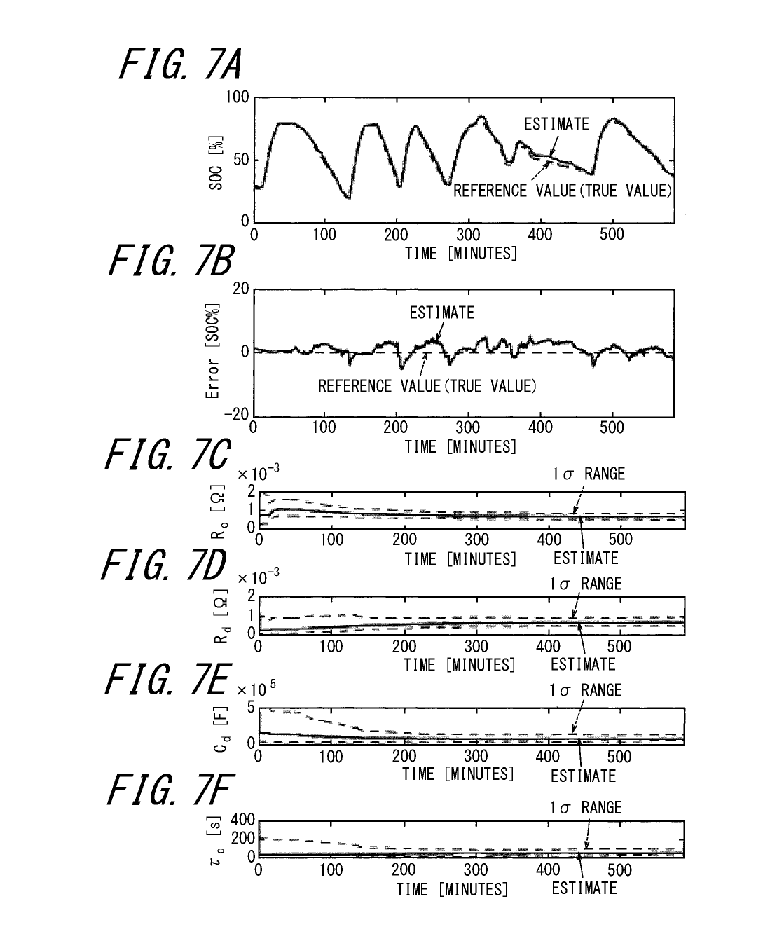

FIG. 7 illustrates the results of estimation by the estimation device 1 according to the disclosure. FIG. 7(a) illustrates the SOC estimate by the estimation device 1 and the reference value (true value). FIG. 7(b) illustrates the SOC error rate. As illustrated in FIGS. 7(a) and (b), the estimation device 1 according to the disclosure can estimate the value extremely close to the reference value. FIG. 7(c) to (f) illustrate the estimates of the respective parameters (Rₒ, R_{d}, C_{d}, τ₀) of the battery 2. In each of FIG. 7(c) to (f), the range (1σ range) that is 1σ away from the estimate where σ is the deviation of the estimate is indicated by the dotted lines. The estimate of each parameter of the battery 2 converges to a constant value, and the 1σ range narrows with time, demonstrating that estimation accuracy is maintained.

A comparison table of the root-mean-square error (RMSE) of SOC estimation in the case where the SOC of the battery 2 is estimated by each of the EKF, the UKF, and the MKF is shown below, for reference. As can be understood from the table, the MKF employed by the estimation device 1 according to the disclosure has the smallest RMSE and so has the highest estimation accuracy.

TABLE 1

| Method | EKF | UKF | MKF |
|---|---|---|---|
| RMSE | 2.71% | 2.58% | 2.14% |

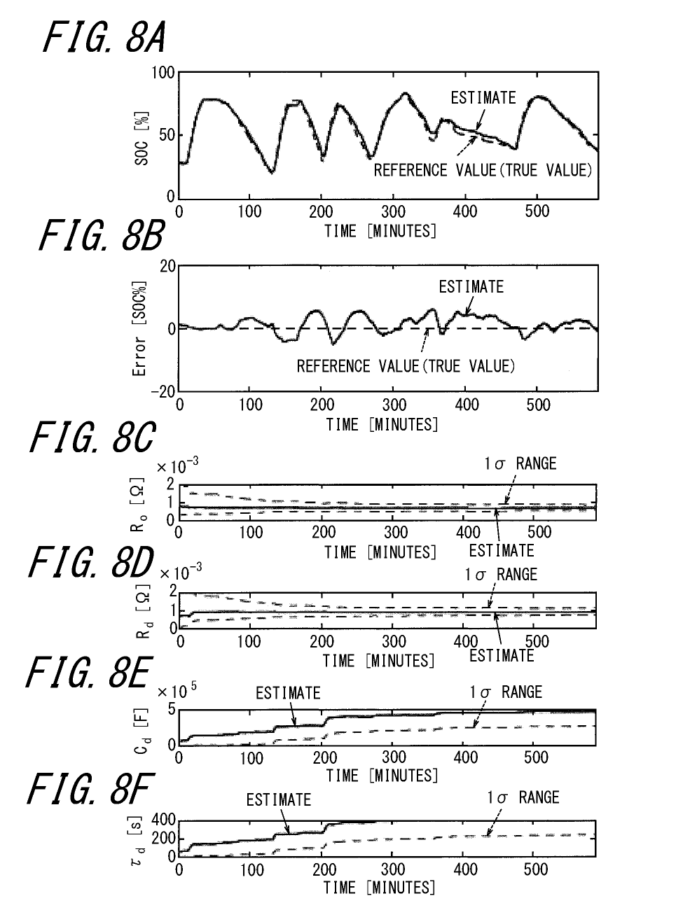

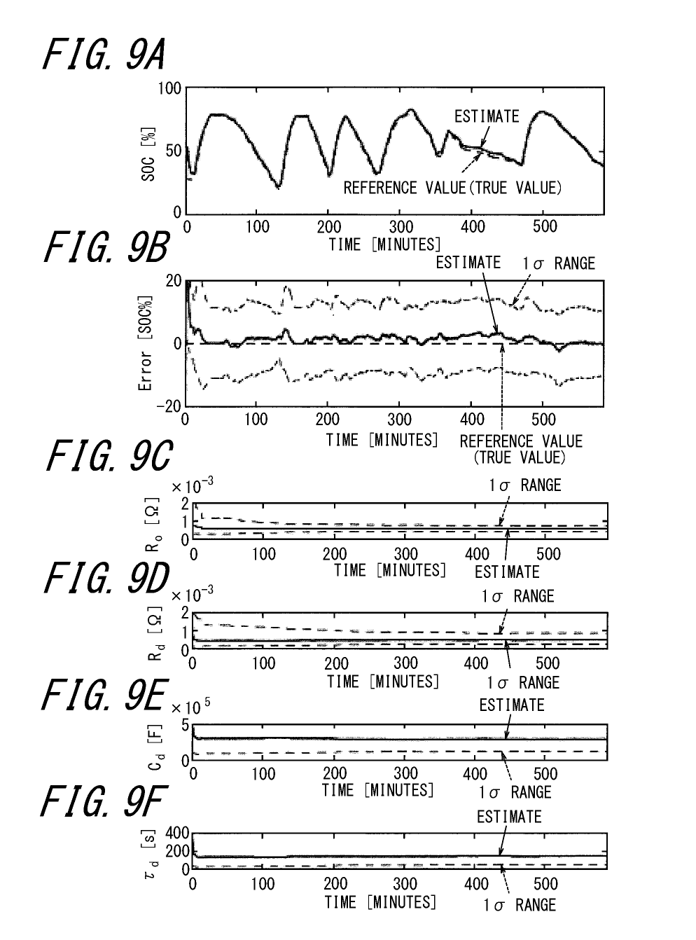

FIGS. 8 and 9 respectively illustrate the results of estimating the SOC and each parameter of the battery 2 using only the EKF and using only the UKF. Regarding the SOC estimation results, the EKF and the UKF both have a certain level of estimation accuracy (FIGS. 8(a) and (b), and FIGS. 9(a) and (b)). When the SOC estimation results according to the disclosure (FIGS. 7(a) and (b)) are compared with these results, the estimation results according to the disclosure are such that the estimate converges in the initial stage at a speed similar to that of the EKF, and also the range of deviation is reduced. The results by the MKF thus have the highest estimation accuracy.

Regarding the estimation results of each parameter of the battery 2 by the EKF (FIG. 8(c) to (f)), some parameters increase stepwise, and also the 1σ range does not converge (FIGS. 8(e) and (f)). The EKF thus has poor estimation accuracy for these parameters. Regarding the estimation results of each parameter of the battery 2 by the UKF (FIG. 9(c) to (f)), on the other hand, each parameter converges to a constant value, and the 1σ range converges, too. The estimation results of each parameter according to the disclosure (FIG. 7(c) to (f)) are similar to the estimation results of each parameter by the UKF.

As described above, the estimation device 1 in Example 1 performs estimation using the MKF which is the combination of the EKF and the UKF. In the prior estimation prediction phase in which estimation is performed using the UKF, since there are seven state variables in Example 1, 15 sigma points in the UKF are generated and calculation is performed for each sigma point. This enables accurate calculation in the prior estimation prediction phase, even though the state equation is strongly nonlinear. In the prior estimation update phase, on the other hand, calculation is performed using the EKF. The output equation is weakly nonlinear, and so high-accuracy estimation is possible even with the EKF. Moreover, since the EKF uses only one point for estimation, the number of operations can be reduced to about 1/15 as compared with the case where 15 sigma points are generated and each subjected to calculation. The estimation device 1 in Example 1 can therefore reduce computational load and enhance estimation accuracy.

### Example 2

### Estimation of Internal State Quantity in Human Face Tracking

The following describes an estimation device for estimating an internal state quantity in human face tracking using the MKF algorithm according to the disclosure. The estimation device in Example 2 roughly differs from the structure in Example 1 in that the EKF is used in the prior estimation prediction phase and the UKF is used in the prior estimation update phase.

The state equation relating to human face tracking is

$$\begin{matrix}[ Math . 23 ] & \\ {[ \begin{matrix}x \\ y \\ \dot{x} \\ \dot{y}\end{matrix} ]}_{k} = {[ \begin{matrix}1 & 0 & τ & 0 \\ 0 & 1 & 0 & τ \\ 0 & 0 & {a}_{x} & 0 \\ 0 & 0 & 0 & {a}_{y}\end{matrix} ] [ \begin{matrix}x \\ y \\ \dot{x} \\ \dot{y}\end{matrix} ]}_{k - 1} + [ \begin{matrix}0 \\ 0 \\ {b}_{x} \\ {b}_{y}\end{matrix} ] {v}_{k} & ( 55 )\end{matrix}$$

(Rudolph van der Merwe, “Sigma-Point Kalman Filters for Probabilistic Inference in Dynamic State-Space Models”, A dissertation submitted to the faculty of the OGI School of Science & Engineering at Oregon Health &

Science University in partial fulfillment of the requirements for the degree Doctor of Philosophy in Electrical and Computer Engineering, April, 2004, p. 290), where τ is a sampling period, and

[Math. 24]

bₓ= v̅\sqrt{1−aₓ²} (56)

b_{y}= v̅\sqrt{1−a_{y}²} (57)

The output equation relating to human face tracking is

$$\begin{matrix}[ Math . 25 ] & \\ [ \begin{matrix}{z}_{x}^{( 1 )} \\ {z}_{y}^{( 1 )} \\ {z}_{x}^{( 2 )} \\ {z}_{y}^{( 2 )} \\ ⋮ \\ {z}_{x}^{( K )} \\ {z}_{y}^{( K )}\end{matrix} ] = [ \begin{matrix}{\tilde{x}}_{k}^{( 1 )} + {x}_{k} \\ {\tilde{y}}_{k}^{( 1 )} + {y}_{k} \\ {\tilde{x}}_{k}^{( 2 )} + {x}_{k} \\ {\tilde{y}}_{k}^{( 2 )} + {x}_{k} \\ ⋮ \\ {\tilde{x}}_{k}^{( K )} + {x}_{k} \\ {\tilde{y}}_{k}^{( K )} + {x}_{k}\end{matrix} ] + {n}_{k} & ( 58 )\end{matrix}$$

according to the same dissertation, where

$$\begin{matrix}[ Math . 26 ] & \\ {\tilde{x}}_{k}^{( r )} = \sqrt{\frac{{( tan {θ}_{k}^{( r )} )}^{2}}{1.44 {( tan {θ}_{k}^{( r )} )}^{2} + 1}} & ( 59 ) \\ {\tilde{y}}_{k}^{( r )} = \sqrt{\frac{1}{1.44 {( tan {θ}_{k}^{( r )} )}^{2} + 1}} & ( 60 )\end{matrix}$$

and θ is the angle seen from the center of the ellipse. In this example, the state equation represented by Expression (55) is relatively close to linearity, i.e. is weakly nonlinear. On the other hand, the output equation represented by Expression (58) has complex nonlinearity, i.e. is strongly nonlinear. Accordingly, when applying the MKF to this example, the EKF is used in the prior estimation prediction phase, and the UKF is used in the prior estimation update phase. In this way, the estimation device according to Example 2 can reduce computational load and enhance estimation accuracy when estimating the internal state quantity in human face tracking.

Although Examples 1 and 2 describe the case of applying the MKF to the estimation of the internal state quantity of the battery and the estimation of the internal state quantity in human face tracking respectively, the system s to which the disclosure is applicable are not limited to these, and the MKF according to the disclosure can be applied to any other nonlinear system to perform state estimation of an internal state quantity.

Here, a computer may be suitably used to function as the estimation device. A program in which the processes for achieving the functions of the estimation device are written may be stored in a storage unit in such a computer, with a central processing unit (CPU) of the computer reading and executing the program to function as the estimation device.

Although the disclosed device and method have been described by way of the drawings and examples, various changes and modifications may be easily made by those of ordinary skill in the art based on this disclosure. Such various changes and modifications are therefore included in the scope of this disclosure. For example, the functions included in the means, steps, etc. may be rearranged without logical inconsistency, and a plurality of means, steps, etc. may be combined into one means, step, etc. and a means, step, etc. may be divided into a plurality of means, steps, etc.

### REFERENCE SIGNS LIST

1 estimation device
2 battery
11 current sensor
12 voltage sensor
13 controller
131 interface unit
132 control unit
133 storage unit
134 output unit

1. An estimation device for estimating an internal state quantity in a nonlinear system using a nonlinear Kalman filter,
wherein the nonlinear Kalman filter includes: a prior estimation prediction phase in which a prior state estimate and a prior covariance matrix of a state are calculated based on a state equation relating to the nonlinear system; and a prior estimation update phase in which a prior output estimate, a covariance matrix of an output, and a cross covariance matrix of the state and the output are calculated based on an output equation relating to the nonlinear system, and
an extended Kalman filter (EKF) is used in one of the prior estimation prediction phase and the prior estimation update phase, and an unscented Kalman filter (UKF) is used in the other one of the prior estimation prediction phase and the prior estimation update phase.

2. The estimation device according to claim 1,
wherein the EKF is used in a phase corresponding to a weakly nonlinear equation, based on the state equation and the output equation.

3. The estimation device according to claim 1,
wherein the UKF is used in a phase corresponding to a strongly nonlinear equation, based on the state equation and the output equation.

4. The estimation device according to claim 1,
wherein the nonlinear system is a battery, and the internal state quantity includes a state of charge (SOC) of the battery, and
the UKF is used in the prior estimation prediction phase, and the EKF is used in the prior estimation update phase.

5. An estimation method for estimating an internal state quantity in a nonlinear system using a nonlinear Kalman filter,
wherein the nonlinear Kalman filter includes: a prior estimation prediction phase in which a prior state estimate and a prior covariance matrix of a state are calculated based on a state equation relating to the nonlinear system; and a prior estimation update phase in which a prior output estimate, a covariance matrix of an output, and a cross covariance matrix of the state and the output are calculated based on an output equation relating to the nonlinear system, and
an extended Kalman filter (EKF) is used in one of the prior estimation prediction phase and the prior estimation update phase, and an unscented Kalman filter (UKF) is used in the other one of the prior estimation prediction phase and the prior estimation update phase.

6. The estimation method according to claim 5,
wherein the EKF is used in a phase corresponding to a weakly nonlinear equation, based on the state equation and the output equation.

7. The estimation method according to claim 1,
wherein the UKF is used in a phase corresponding to a strongly nonlinear equation, based on the state equation and the output equation.

8. The estimation method according to claim 1,
wherein the nonlinear system is a battery, and the internal state quantity includes a state of charge (SOC) of the battery, and
the UKF is used in the prior estimation prediction phase, and the EKF is used in the prior estimation update phase.
